(19) United States
(12) Patent Application Publication
(10) Pub. No.: US 2009/0085055 A1
(43) Pub. Date: Apr. 2, 2009

(54) Method for Growing an Epitaxial Layer

(76) Inventors: Hui Peng, Fremont, CA (US); Heng Liu, Sunnyvale, CA (US)

Correspondence Address: The Law Offices of Calvin B. Ward, Suite 305, 18 Crow Canyon Court, San Ramon, CA, 94583, US

(21) Appl. No.: 11/863,074

(22) Filed: Sep. 27, 2007

(51) Int. Cl. B32B 3/10; H01L 33/00

(52) U.S. Cl. 257/103; 428/195.1; 438/34; 257/E33.013

(57) ABSTRACT

A method for growing an epitaxial layer and devices obtained by that method are disclosed. The method starts by providing a growth substrate having a top surface characterized by a first thermal expansion coefficient (TEC). A mask having a plurality of openings therein is formed on the top surface of the growth substrate. The top surface of the growth substrate is exposed through the openings in the mask. A first epitaxial layer of a first material is grown on the exposed top surface of the openings to form discrete islands of the first material. The discrete islands from adjacent openings in the mask do not contact one another. The first epitaxial layer is characterized by a second TEC. The first and second TECs differ by more than 5 percent. The mask includes a mask material on which the first material will not nucleate.

### BACKGROUND OF THE INVENTION

A number of semiconductor devices are fabricated by growing a number of epitaxial layers on a substrate. For example, one class of light emitting diodes (LEDs) is constructed by growing a number of epitaxially grown layers of gallium-based semiconductors on a sapphire substrate. The yield of devices from the fabrication process is reduced by dislocation defects in the epitaxial layer. These dislocations can result from mismatches between the lattice constants of the substrate and the epitaxial layer or from mismatches in the thermal expansion coefficients (TECs) between the epitaxial layer and the substrate. In the case of gallium-based semiconductors grown on sapphire, significant mismatches between both the thermal expansion coefficients and the lattice constants exist. The dislocation density resulting from the lattice constant mismatch has been significantly reduced by utilizing buffer layers and other techniques. However, the dislocations resulting from the TEC mismatch remain.

A mismatch in the TEC between the substrate and the epitaxial layer results in stress being applied to the epitaxial layer. The stress in the epitaxial layer is cumulative, and hence, the stress increases with the size of the wafer. The degree of mismatch increases with the distance from the center of the wafer. Hence, the density of dislocation defects is higher at the edges of the wafer than in the middle.

Techniques for reducing the density of dislocations have been suggested. One class of techniques utilizes epitaxial lateral over-growth (ELO). In these techniques, islands of material on which the epitaxially grown material will not nucleate are provided on the surface of the substrate. The epitaxially grown material begins to grow between the islands. As the height of the layer increases to the height of the islands, the epitaxial material grows laterally over the islands and finally forms a continuous layer over the substrate. This technique reduces dislocations from lattice mismatch; however, dislocations from TEC mismatch are still significant. During the epitaxial growth, epitaxial layers growing in adjacent openings coalesce to form a large layer that covers the islands and the substrate. During the cooling cycle, stress builds in the epitaxial layer due to the TEC mismatch between the epitaxial layer and the growth substrate. The stress is especially high in large thick epitaxial layers and leads to dislocation defects. In addition, there are also defects at the interfaces at which the epitaxial layers from adjacent openings meet. Hence, ELO techniques still lead to epitaxial layers that have significant levels of defects.

A second class of ELO techniques utilizes a gap between two islands on which the epitaxially grown material nucleates. The layers from the islands extend out laterally over the gap until the extending layers touch and form a continuous epitaxial layer that overlies the gap. The area over the gap has reduced levels of dislocations resulting from lattice mismatches relative to that over the islands. However, the epitaxial layer is subjected to high thermal stresses during cooling cycles, and hence, suffers from TEC induced dislocations.

### SUMMARY OF THE INVENTION

The present invention includes a method for growing an epitaxial layer and the device obtained by that method. The method starts by providing a growth substrate having a top surface characterized by a first thermal expansion coefficient (TEC). A mask having a plurality of openings therein is formed on the top surface of the growth substrate. The top surface of the growth substrate is exposed through the openings in the mask. A first epitaxial layer of a first material is grown on the exposed top surface of the openings to form discrete islands of the first material. The discrete islands from adjacent openings in the mask do not contact one another. The first epitaxial layer is characterized by a second TEC. The first and second TECs differ by more than 5 percent. The mask includes a mask material on which the first material will not nucleate. The discrete islands can be completely contained within the openings in the mask or part of the discrete islands overlie a region of the mask outside of the openings. The first epitaxial layer can include a buffer layer and a first-type cladding layer. An active layer and a second epitaxial layer of a second semiconductor type can be grown on top of the first epitaxial layer to form a light emitting structure.

### BRIEF DESCRIPTION OF THE DRAWINGS

FIGS. 1A-1D are cross-sectional views of a portion of a substrate at various stages of the growth of an epitaxial layer over the substrate utilizing a prior art lateral growth method.

FIGS. 2A and 2B illustrate the fabrication of an epitaxial layer according to one embodiment of the present invention.

FIGS. 3A and 3B are cross-sectional views of a section of a wafer at different phases of the fabrication process.

FIGS. 4A and 4B are cross-sectional views of a portion of a substrate at different phases of the fabrication of two devices that are similar to the devices discussed in FIGS. 3A and 3B.

FIG. 5A is a top view of a wafer 501.

FIG. 5B is a cross-sectional view through line 5B-5B shown in FIG. 5A.

FIG. 5C is a top view of one of the epitaxial structures shown in FIG. 5A.

FIGS. 6A and 6B illustrate the construction of LEDs using an overlapping structure.

FIGS. 7A and 7B illustrate the construction of an optical device having a more conventional epitaxial layer structure.

FIGS. 8A-8C illustrate a photo-resist assisted planarization method that could be used with the method of the present invention.

FIGS. 9A and 9B illustrate a masked substrate in which the masks have openings that are circular and hexagonal, respectively.

### DETAILED DESCRIPTION OF THE PREFERRED EMBODIMENTS OF THE INVENTION

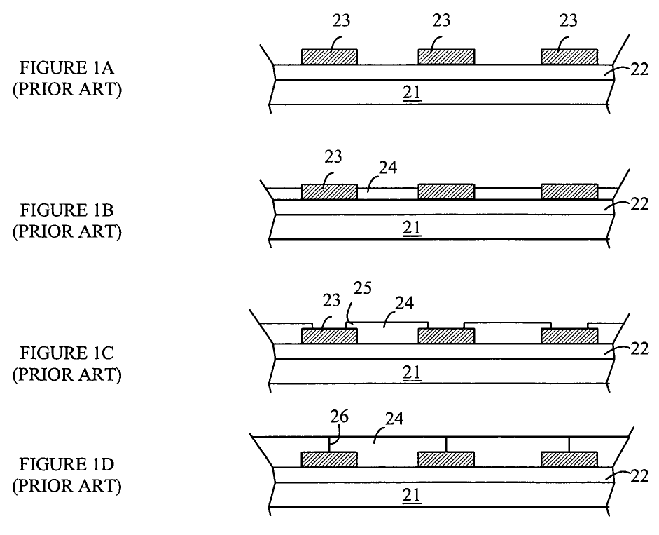

The manner in which the present invention provides its advantages can be more easily understood with reference to FIGS. 1A-1D, which are cross-sectional views of a portion of a substrate at various stages of the growth of an epitaxial layer over the substrate utilizing a prior art lateral growth method. Referring to FIG. 1A, an epitaxial layer 22 is grown on a substrate 21. A mask 23 is then patterned on epitaxial layer 22. The mask material is chosen such that the material from which the subsequent epitaxial layer is grown will not nucleate on mask 23. A second epitaxial layer is then deposited on layer 22 as shown in FIGS. 1B-1D. Referring to FIG. 1B, epitaxial layer 24 is initially confined to the openings in mask 23, since the material from which epitaxial layer 24 is constructed will not nucleate on the surface of mask 23. When epitaxial layer 24 becomes thicker than the depth of the openings in mask 23, epitaxial layer 24 begins to grow laterally over the top surface of mask 23 as shown in FIG. 1C at 25. Finally, epitaxial layer 24 extends laterally over the top surface of mask 23 forming a solid layer that overlies the entire substrate. It is found experimentally that the density of dislocation defects arising from lattice mismatches between substrate 21 and layer 24 is substantially reduced in the area overlying mask 23 with the exception of the defect shown at 26.

While this method of growing an epitaxial layer leads to fewer dislocation defects from lattice mismatches, it does not reduce defects from differences in the TEC of the substrate and epitaxial layer materials. The final epitaxial layer extends over the entire substrate, and hence, suffers from the same cumulative TEC stress problems as layers that are deposited without the masks. In some cases, this prior art method actually aggravates the TEC defect problem, since epitaxial layer 24 must be thicker than would be the case if the mask was not utilized, and thicker layers are more subject to thermal stress-induced defects.

The present invention avoids the cumulative stress problems by utilizing an epitaxial layer that does not extend over the entire substrate, and hence, has reduced cumulative stress. The present invention divides the epitaxial layer into sections that do not contact one another, and hence, the single solid epitaxial layer that gives rise to increased TEC dislocations is avoided.

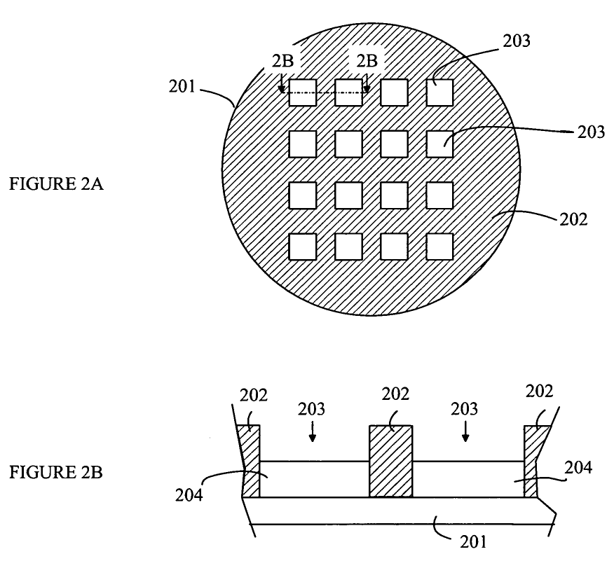

Refer now to FIGS. 2A and 2B which illustrate the deposition of an epitaxial layer according to one embodiment of the present invention. FIG. 2A is a top view of substrate 201, FIG. 2B is a cross-sectional view of the masked substrate through line 2B-2B shown in FIG. 2A. The epitaxial layer is deposited on a substrate 201 that is covered by a mask 202 having openings 203 therein. The mask is constructed from a material on which the material of the epitaxial layer will not nucleate during deposition. Hence, when the epitaxial layer material is deposited over the masked wafer, the material accumulates in the openings but not on the surface of the mask. The height of the epitaxial layer is chosen such that the layer is less than the height of the mask, and hence, the epitaxial layer does not form a continuous layer over the substrate. During cooling cycles, the stress on the epitaxial layer due to the differences in TEC between the epitaxial layer and the substrate are limited by the size of the individual epitaxial layer sections 204 within the wells in mask 202. Hence, the buildup of stress across an entire wafer-sized layer is avoided.

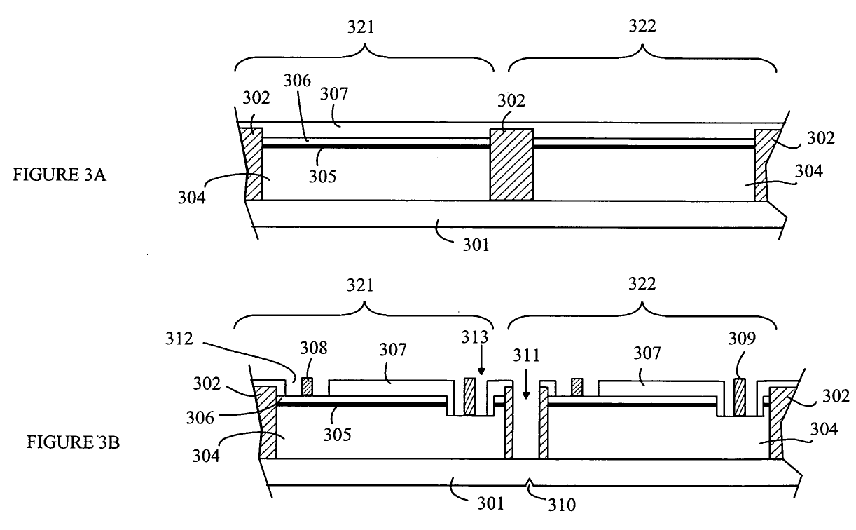

The manner in which the method of the present invention can be utilized to fabricate an LED can be more easily understood with reference to FIGS. 3A and 3B, which are cross-sectional views of a section of a wafer at different phases of the fabrication process. The section of the wafer shown in these figures corresponds to two LEDs 321 and 322. Referring to FIG. 3A, the process starts by providing an epitaxial wafer having a growth substrate 301 with a mask 302 in a manner analogous to that described above. The openings in the mask are sized to correspond to approximately the dimensions of the final LED chips. The mask is formed from an electrically insulating material that can withstand the temperatures encountered in the subsequent epitaxial growth steps. For the purposes of this example, it will be assumed that the substrate is sapphire.

An N-type cladding layer 304 is formed in the bottom of the openings in the mask and an active layer 305 is then grown on top of the N-type layer. A P-type cladding layer 306 is then grown on the active layer. While the various layers are shown as single layers, it will be appreciated that each layer can be formed from a number of sub-layers having different compositions. In addition, the cladding sub-layer grown directly on the substrate could be a buffer layer or layers selected to reduce the dislocations arising from the lattice mismatch between the substrate and the epitaxial layer. The top surface of cladding layer 306 may be either at the same level as that of the sidewall of mask 302 or lower than that of the sidewall of mask 302. The top surface of cladding layer 306 can be processed to provide a rough surface to improve light extraction at this stage in the processing. In addition, other layers such as a current spreading layer could be deposited on the top surface of cladding layer 306. Finally, a protective layer 307 is grown over the wafer. In the example shown in FIG. 3A, the top surface of the protective layer is higher than that of the sides of the mask; however, embodiments in which the protective layer is at the height of the mask or contained within the wells in the mask can also be utilized.

In the next stage of processing, contacts to cladding layers 304 and 306 are provided and the layered stack is processed for subsequent singulation of the individual LEDs. Refer now to FIG. 3B. The contact to cladding layer 306 is provided by etching an opening 312 in layer 307 to expose the top surface of cladding layer 306. An electrical contact 308 is subsequently deposited in this opening. Similarly, a second opening 313 is etched in layer 307 to expose the top surface of cladding layer 304. Layers 305, 306, and part of layer 304 are then removed to expose layer 304 so that an electrical contact 309 can be subsequently deposited. The exposed surfaces of layers 304 and 306 are protected by depositing an insulating material on the vertical surfaces of opening 313.

After contacts 308 and 309 are deposited, the sidewalls of the mask are etched down to substrate 301 as shown at 311 and the bottom surface of substrate 301 is scribed as shown at 310 to facilitate the final singulation of the individual dies. The portion of the mask that remains after the singulation provides a protective sidewall on all sides of the dies, which reduces current leakage between layers 304 and 306.

It should be noted that the specific singulation process depends on the material from which substrate 301 is formed. If the substrate allows singulation of the individual dies by sawing, the areas of the mask between the dies could merely be sawed to singulate the dies.

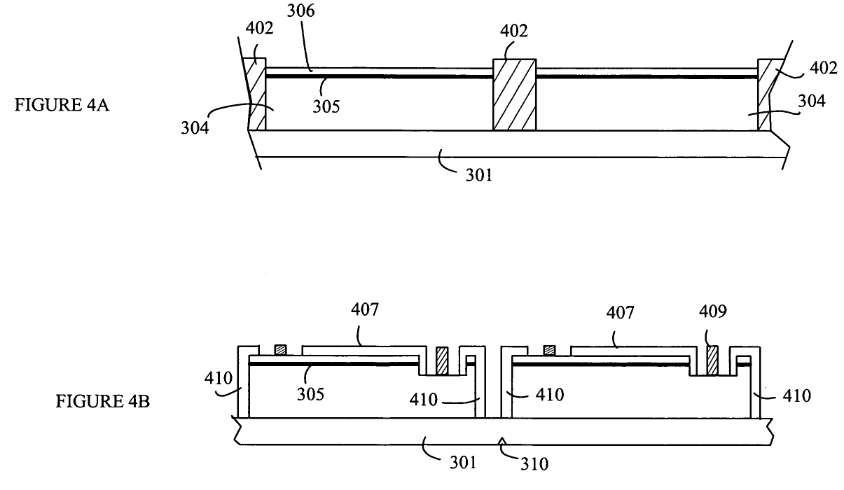

The above-described embodiments utilize a mask that is constructed from a patterned layer of electrically insulating material such as SiO₂. However, embodiments that utilize masks constructed from a patterned metallic layer can also be employed. Refer now to FIGS. 4A and 4B, which are cross-sectional views of a portion of a substrate at different stages of two devices that are similar to devices 321 and 322 discussed above. In this embodiment of the present invention, the mask 402 is constructed from a metal such as tungsten. The various layers of the devices are grown in a manner analogous to that described above. After cladding layer 306 is grown, the mask is removed by etching to avoid electrical shorting of the various layers in the final device. Referring to FIG. 4B, after the mask is removed, a protective layer 407 that includes sidewalls 410 is deposited on the wafer. Layer 407 is patterned to provide the openings required for the deposition of the various electrical contacts such as contact 409 in a manner analogous to that described above. Protective sidewalls 410 are preferably separated by an amount that is greater than or equal to the width of the singulation “streets” for the particular fabrication process used to construct the wafers.

In the above-described embodiments of the present invention, the devices started with a masked substrate and were completed by growing all of the epitaxial layers in succession in the reactor. However, it should be noted that the process could be halted after one or more layers are grown on the substrate within the mask openings. The resultant substrate could then be used as a starting substrate for constructing a large variety of different devices. For example, a starting growth substrate consisting of the masked substrate with one or more sub-layers of the first cladding layer could be constructed. Similarly, a starting growth substrate having one or more buffer layers grown in the mask openings could be provided. Such buffer layers are often used to reduce dislocations resulting from lattice mismatches between the substrate and the device material system in which the active device is constructed. The resulting growth substrate could then be used as a starting point for any device that utilized the device material system.

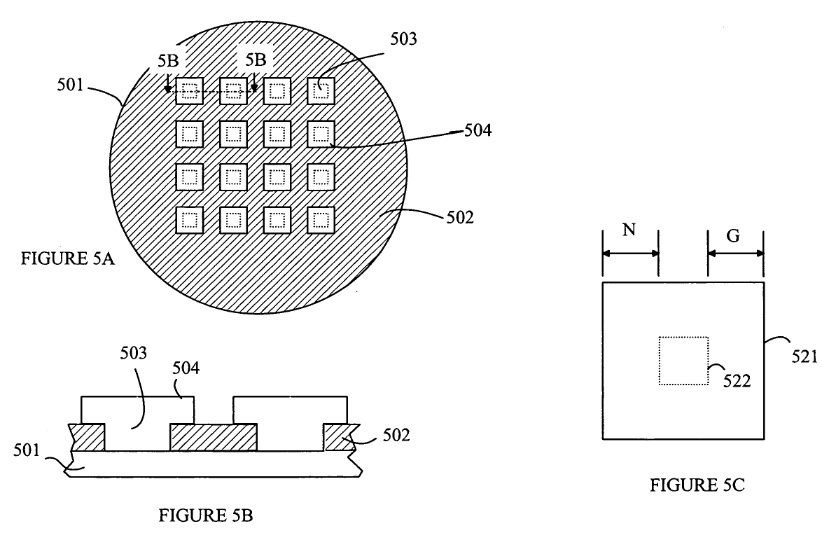

The above-described devices were confined to the opening in the mask. However, devices that extend beyond the opening in the mask can also be constructed utilizing the present invention. Refer now to FIGS. 5A and 5B, which illustrate the growth of an epitaxial layer that extends above and beyond the opening in the mask. FIG. 5A is a top view of a wafer 501, and FIG. 5B is a cross-sectional view through line 5B-5B shown in FIG. 5A. Wafer 501 is covered with a mask 502 having openings 503 therein. The mask is constructed from a material on which the epitaxially grown material will not nucleate. When the epitaxial material is grown on wafer 501, the epitaxial layer crystallizes in the openings in the mask and continues to grow until the epitaxial layer achieves a thickness that is greater than that of mask 502. At this point, the epitaxial layer will grow in thickness and begin to extend over the surface of mask 502 as shown at 504. The growth is stopped before the epitaxial layers have grown to the point at which the epitaxial layers touch.

It should be noted that the lateral growth rate could be significantly different in one direction than in another direction depending on the particular material being grown. Refer now to FIG. 5C, which is a top view of one of the epitaxial structures shown in FIG. 5A. Epitaxial structure 521 is grown from an opening 522 in the mask. The N and G dimensions shown in FIG. 5C depend on the lateral growth rate of the epitaxial layer in different directions with respect to the crystal planes of the material being grown; hence, if the growth rates on the different crystal planes are different, N will be different from G. For example, for a non-polar GaN epitaxial layer, the growth rate in the Ga-plane is about 4 to 12 times faster than that in the N-plane depending on the growth conditions and equipment. Therefore width N would be less than width G in the resulting structure.

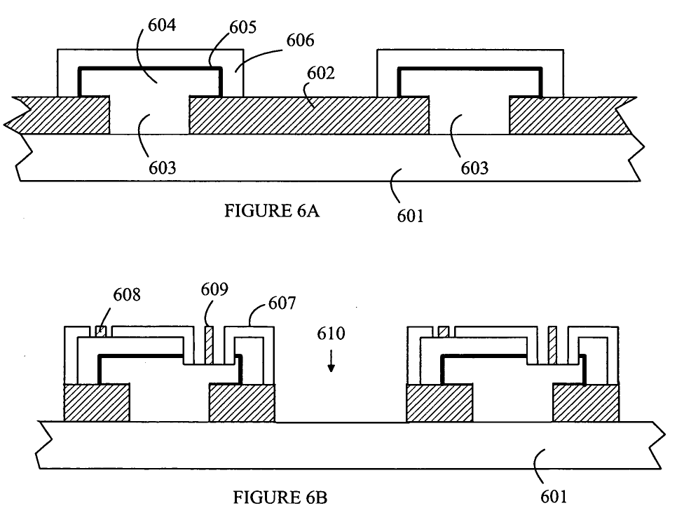

The overhanging structure discussed above can be utilized to construct an LED or similar structure. Refer now to FIGS. 6A and 6B, which illustrate the construction of LEDs using such an overlapping structure. The process starts by growing an n-cladding layer 604 in the openings 603 in mask 602 on substrate 601 in a manner analogous to that discussed above with respect to FIGS. 5A and 5B. Next, the active region layers 605 and the p-cladding layers 606 are grown by altering the compositions of the material in the reaction chamber leaving the substrate as shown in FIG. 6A. Referring to FIG. 6B, a protective layer 607 is then deposited over the outer cladding layer and patterned to provide access to both cladding layers 604 and 606. Access to cladding layer 604 is provided by etching through layers 605 and 606. The metal contacts 608 and 609 are then deposited and the region of the mask between the devices removed as shown at 610 to facilitate singulation of the devices.

Depending on the specific features of the device being fabricated, the outer surface of cladding layer 606 could be processed further before depositing protective layer 607. For example, the surface could be textured to provide improved light extraction and/or additional layers such as a current spreading layer could be added to improve the distribution of the current introduced by contact 608.

It should be noted that the active layer 605 surrounds the sides of the device in the embodiments shown in FIG. 6B. This feature provides improved performance by reducing the current leakage between the n-type cladding layer and the p-type cladding layer. In addition, the side portions of the active layer provide an increased light generation area without increasing the size of the die.

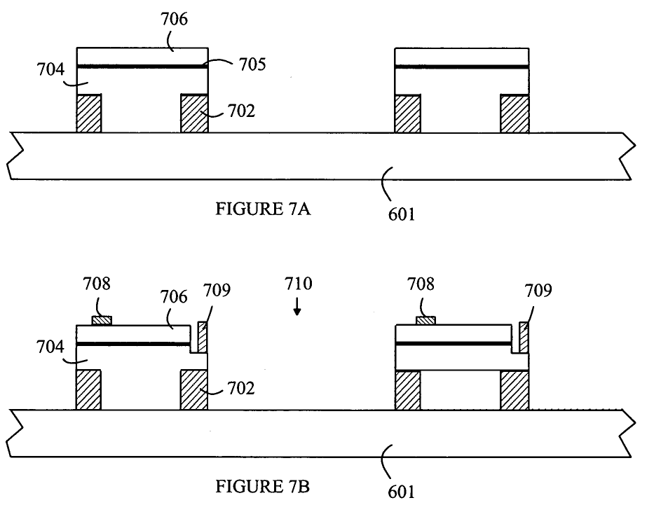

Embodiments of devices that lack the additional sides on the active layer can also be constructed by etching the overlapping structure after the second cladding layer has been deposited. Refer now to FIGS. 7A and 7B, which illustrate the construction of an optical device having a more conventional epitaxial layer structure. The process starts by depositing an overlapping three-layered structure such as that shown in FIG. 6A discussed above. The sides of the overlapping structure are then etched using ICP dry etching to remove the portions of the active layer that extend in the vertical direction. The etching also removes the portion of mask 702 that extends between the devices leaving a singulation street 710. The resulting structure is shown in FIG. 7A. The individual devices have a three-layered structure with an active layer 705 that is parallel to the surface of substrate 601, and a top cladding layer 706 that consists of a plane that is parallel to active layer 705. A portion of mask 702 is included in bottom cladding layer 704 in the embodiments shown in FIGS. 7A and 7B. The etching of the sidewalls can be executed either before or after any surface treatments of cladding layer 706 have been carried out. Finally, layers 704-706 are etched to provide access to layer 704 for contact 709. Contacts 708 and 709 are then deposited as shown in FIG. 7B.

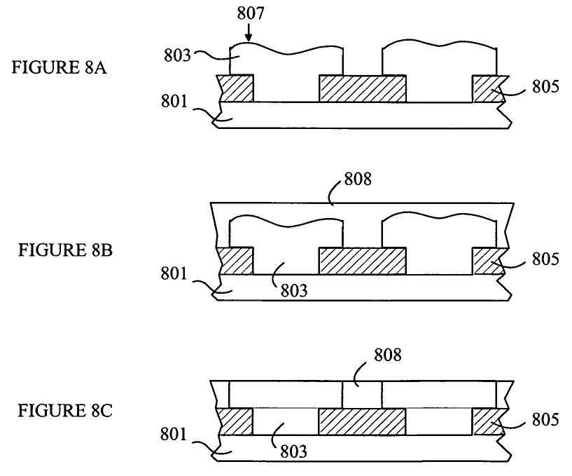

The above-described embodiments of the present invention assume that the first cladding layer has a surface that is sufficiently smooth to allow the growth of the active layer and the second cladding layer. If this is not the case, the substrate can be removed from the reactor after the growth of the first cladding layer and planarized. Any of a number of methods can be utilized for the planarization. For example, the top surface of the wafer could be planarized by chemical mechanical polishing or by photo-resist assisted etching. Refer now to FIGS. 8A-8C, which illustrate a photo-resist assisted planarization method that could be used with the method of the present invention after the first epitaxial layer has been grown on substrate 801. For the purposes of this example, it will be assumed that the first cladding layer has been grown to a height that extends above mask 805 that defines the first cladding layer as shown in FIG. 8A. It will be assumed that the top surface of the first cladding layer is non-planar as shown at 807. Referring to FIG. 8B, a layer of photo-resist 808 is applied to the wafer by spin casting. The top surface of the photo-resist layer is planarized by the spin casting operation. The photo-resist is chosen to have an etch rate that is the same or similar to the etch rate of the first cladding layer 803. As a result, the top surface of the first cladding layer features will be etched without etching the side surfaces of the features. Since non-planar areas are etched at a faster rate than planar areas, the top surface of the first cladding layer will be planarized leaving the surface as shown in FIG. 8C. The portions of photo-resist layer 808 that remain between the first cladding layers are then removed.

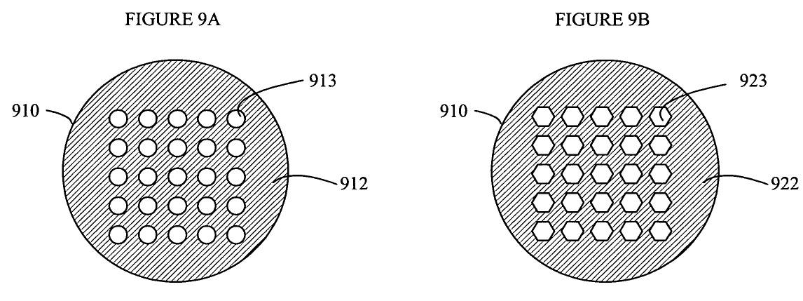

The above-described embodiments of the present invention utilize a mask having a rectangular opening, and hence, the resultant devices are substantially rectangular in shape. However, devices having other shapes can be fabricated by utilizing a mask with different shaped openings. Refer now to FIGS. 9A and 9B, which illustrate a masked substrate 910 in which the masks 912 and 922 have openings 913 and 923 that are circular and hexagonal, respectively. If the epitaxial layers are confined to the mask, i.e., the height of the epitaxial layers is less than that of the mask, then the shape of the device will be determined by the mask. If the epitaxial layers are allowed to continue growing over the mask as discussed above with reference to FIGS. 6A and 6B, then the shape of the device in the region over the mask will be determined by a combination of factors, including the shape of the opening in the mask, the crystalline properties of the material being grown, and the extent of the overgrowth. For example, if the mask openings are circular in shape and the devices are confined to the opening in the mask, LEDs or similarly structured devices having a circular geometry can be fabricated. Similarly, if the openings are polygons such as hexagons, devices having hexagonal geometries can be fabricated.

As noted above, the present invention utilizes a mask material on which the epitaxial grown material will not nucleate. Exemplary mask materials include dielectric materials, metals, alloys, and their combinations. Examples of such materials are SiO₂, SiₓN_{y}, Tungsten W, Ti/W, Ni/W, Cr/W, SiₓN_{y}/W, Ti/SiₓN_{y}/W, SiO₂/W, and Ti/SiO₂/W. The specific material will depend on the choice of epitaxial layer material. The method of the present invention can be utilized with a wide variety of epitaxially grown materials. Exemplary epitaxial layer materials include compositions of elements of Al, In, B, Ga, N, P, As, Zn, and O. Exemplary compositions include (Al, In, B, Ga)N, (Al, In, B, Ga)P, (Al, In, B, Ga)NP, (Al, In, Ga)As, ZnO, AlN, GaN, GaInN, AlInGaN, BInGaN, GaP, InP, GaInP, AlGaInP, BGaInP, GaNP, GaInNP, AlInGaNP, BInGaNP, GaInAs, AlGaInAs, and ZnO.

The thickness of the mask layer will depend, in general, on the particular device being fabricated. A Mask thickness from 0.01 μm to 8 μm is particularly useful in fabricating optical devices such as LEDs and lasers. The openings in the mask are approximately the size of the final useful area of the chip in embodiments in which the device is constrained to the dimensions of the opening. Openings having dimensions of 0.5 mm to 10 cm are useful for fabricating optical devices such as LEDs and laser diodes. In devices in which the epitaxial layer extends laterally over the top surface of the mask, the openings are typically less than the size of the final useful chip area.

The growth substrates on which the epitaxial layer materials are grown also include a wide variety of materials. Exemplary growth substrates include GaN, AlN, SiC, sapphire, silicon, boron nitride, lithium aluminate, lithium niobate, lithium gallate, germanium, ZnO, GaP, InP, and GaAs. The crystal plane of a growth substrate includes the c-plane, the a-plane, and the m-plane.

As noted above, the method of the present invention is particularly advantageous in situations in which the TEC of the epitaxial layer material differs substantially from that of the growth substrate, e.g., TEC differences of 10% or greater. The present invention also provides advantages in situations when the TEC mismatch is as low as 5%. For example, the TEC of GaN is about 5.6×10⁻⁶/° K. GaN epitaxial layers are typically grown on sapphire substrates because lattice mismatch between GaN and sapphire substrates is acceptable in terms of the dislocations caused by the mismatch. However, the TEC of sapphire is about 7.5×10⁻⁶/° K. Other substrates such as SiC also have large TEC mismatches. In the case of SiC, the TEC is 4.2×10⁻⁶/° K.

In the above-described embodiments of the present invention, the first cladding layer was selected to be an n-type layer and the second cladding layer was selected to be a p-type layer. However, embodiments in which the types of the layers are reversed such that the first cladding layer is a p-type layer and the second cladding layer is a n-type layer could also be constructed.

Various modifications to the present invention will become apparent to those skilled in the art from the foregoing description and accompanying drawings. Accordingly, the present invention is to be limited solely by the scope of the following claims.

What is claimed is:

1. A method for growing an epitaxial layer, said method comprising:
providing a growth substrate having a top surface characterized by a first thermal expansion coefficient (TEC);
forming a mask having a plurality of openings therein on said top surface of said growth substrate, said top surface of said growth substrate being exposed through said openings; and
growing a first epitaxial layer of a first material on said exposed top surface of said openings to form discrete islands of said first material, said discrete islands from adjacent openings in said mask not contacting one another, wherein said first epitaxial layer is characterized by a second TEC, said first and second TECs differing by more than 5 percent, wherein said mask comprises a mask material on which said first material will not nucleate.

2. The method of claim 1, wherein said top surface of said growth substrate comprises a material selected from the group comprising GaN, AlN, SiC, sapphire, silicon, boron nitride, lithium aluminate, lithium niobate, lithium gallate, germanium, ZnO, GaP, InP, and GaAs.

3. The method of claim 2 wherein said top surface of said growth substrate consists of a crystal plane selected from the group comprising c-plane, a-plane, and m-plane.

4. The method of claim 1, wherein said first material comprises a material selected from the group comprising compositions of elements of Al, In, B, Ga, N, P, As, Zn, and O; wherein said compositions comprise (Al, In, B, Ga)N, (Al, In, B, Ga)P, (Al, In, B, Ga)NP, (Al, In, Ga)As, and ZnO.

5. The method of claim 1 wherein said discrete islands are completely contained within said openings in said mask.

6. The method of claim 1 wherein part of said discrete islands are within said openings in said mask and part of said discrete islands overlie a region of said mask outside of said openings.

7. The method of claim 1 wherein said first epitaxial layer comprises a buffer layer and a first-type cladding layer.

8. The method of claim 7 further comprising growing a second epitaxial layer on said first-type cladding layer.

9. The method of claim 8 further comprising planarizing said first-type cladding layer prior to growing said second epitaxial layer.

10. The method of claim 8 wherein said second epitaxial layer comprises an active layer and a second-type cladding layer, said active layer generating light when holes and electrons combine therein.

11. The method of claim 8 wherein said active layer has a structure selected from the group consisting of bulk,bulk what? single quantum well, multi-quantum well, quantum dot, and quantum line.

12. The method of claim 1 wherein said mask material is selected from the group consisting of dielectric materials, metals, alloys and their combinations.

13. The method claim 1 wherein said mask material comprises materials selected from SiO₂, SiₓN_{y}, Tungsten (W), Ti/W, Ni/W, Cr/W, SiₓN_{y}/W, SiO₂/W, Cr/SiO₂/W, Cr/SiₓN_{y}/W, Ni/SiO₂/W, Ni/SiₓN_{y}/W, Ti/SiₓN_{y}/W, and Ti/SiO₂/W.

14. The method of claim 1 wherein said growth substrate is divided into a plurality of semiconductor dies and where said mask openings have shapes and dimension that are substantially the same as said dies.

15. The method of claim 14 wherein said openings are circular or polygonal.

16. A device comprising:
an epitaxial layer of a first material deposited on a top surface of a growth substrate comprising a substrate material; and
a mask having an opening therein, at least a portion of said epitaxial layer being within said opening, said mask comprising a material on which said first material does not nucleate, wherein said top surface of said growth substrate consists of a material that is characterized by a first TEC and said first material is characterized by a second TEC, said first and second TECs differing by more than 5 percent.

17. The device of claim 16 wherein said epitaxial layer comprises a buffer layer, a first-type cladding layer, an active layer, a second-type cladding layer, a first electrode electrically connected to said first-type cladding layer, a second electrode electrically connected to said second-type cladding layer.

18. The device of claim 16 wherein the material of said epitaxial layer is selected from a group consisting of compositions of elements of Al, In, B, Ga, N, P, As, Zn, and O; said compositions comprising (Al, In, B, Ga)N, (Al, In, B, Ga)P, (Al, In, B, Ga)NP, (Al, In, Ga)As, and ZnO.

19. The device of claim 18 wherein said first cladding layer comprises a top surface and vertical side surfaces and wherein said active layer comprises sections that are parallel to said vertical side surfaces.

20. A substrate comprising:
a growth substrate having a top surface characterized by a first thermal expansion coefficient (TEC);
a mask having a plurality of openings therein on said top surface of said growth substrate, said top surface of said growth substrate being exposed through said openings; and
a first epitaxial layer of a first material grown on said exposed top surface of said openings to form discrete islands of said first material, said discrete islands from adjacent openings in said mask not contacting one another, wherein said first epitaxial layer is characterized by a second TEC, said first and second TECs differing by more than 5 percent, wherein said mask comprises a mask material on which said first material will not nucleate.

21. The substrate of claim 20 wherein said discrete islands are completely contained within said openings in said mask.

22. The substrate of claim 20 wherein part of said discrete islands are within said openings in said mask and part of said discrete islands overlie a region of said mask outside of said openings.
